(19) United States
(12) Patent Application Publication
(10) Pub. No.: US 2005/0045939 A1
(43) Pub. Date: Mar. 3, 2005

(54) Split-gate memory cell, memory array incorporating same, and method of manufacture thereof

(76) Inventors: Eungjoon Park, Fremont, CA (US); Di-Son Kuo, Fremont, CA (US)

Correspondence Address: ALTERA LAW GROUP, LLC, 6500 CITY WEST PARKWAY, SUITE 100, MINNEAPOLIS, MN, 55344-7704, US

(21) Appl. No.: 10/649,203

(22) Filed: Aug. 27, 2003

(51) Int. Cl. H01L 29/788; H01L 21/8238

(52) U.S. Cl. 257/315; 438/201; 257/316; 438/266; 257/321; 438/263

(57) ABSTRACT

Flash memory cells have a split-gate structure in which the channel region underlies a floating gate of minimum lithography dimension, as well as one or more portions of the control gate that extend along one or more sidewalls of the floating gate. The length of the channel underlying the control gate sidewall portions is independent of the thickness of the floating gate sidewall portions and is smaller than and independent of the minimum lithography dimension. Preferably, the control gate is part of a continuous word line extending over a row of many substantially identical memory cells. Channel length need be no longer that the minimum lithography dimension (the channel portion underlying the floating gate) plus a sufficient additional length to account for the thickness of the inter-poly dielectric on the control gate sidewall or sidewalls, and for sufficient direct control of the channel by the control gate.

### BACKGROUND OF THE INVENTION

1. Field of the Invention

The present invention relates to semiconductor memory, and more particularly to a split-gate memory cell, memory array incorporating same, and method of manufacture thereof

2. Description of the Related Art

Nonvolatile memory retains stored data when power is removed, which makes flash memory particularly useful for many applications such as mobile electronics. The most commonly used flash memory technology is floating gate technology, which includes the ACT (advanced contactless technology) technology of Sharp Corporation of Japan, the DINOR (divided bit line NOR) technology of Mitsubishi Electric Corporation of Japan, the ETOX (EPROM tunnel oxide) technology, the NAND technology, and the AND technology. Among these, the ETOX and ACT technologies are especially suitable for storage applications involving both code and data due to their fast read performance, high reliability, and random access addressing.

Both ETOX and ACT use channel hot electron (“CHE”) tunneling for programming and Fowler-Nordheim (“FN”) tunneling through the channel region for erasing. Although CHE achieves very reliable and effective programming, cell designs using CHE programming are more difficult to scale. The difficulty in scaling relates to the requirement that high voltage be present at the drain of the cell being programmed. A typical CHE programming condition is V_{D}=5V, V_{G}=10V, and V_{S}=V_{B}=0V. If the cells are scaled, punch-through or drain turn-on problems occur in unselected cell on the same bit line as the selected cell. In reaction to these problems, it is common practice to make the channel length of the flash cell much larger than the lithography limitation. An example is shown in FIG. 1, in which as the lithographic resolution is reduced from 180 nm to 130 nm, 110 nm, and finally 90 nm, the reduction in the cell channel length is less.

Even with a relatively longer channel length, ETOX and ACT still have some bit line leakage during the programming operation. This leakage slows down the programming operation and sometimes creates programming failure. Accordingly, various efforts have been made to improve the basic split-gate transistor design for use in nonvolatile memories. One such effort is disclosed in U.S. Pat. No. 6,013,552, issued Jan. 11, 2000 to Oyama. In the Oyama device, an asymmetrical device, the floating gate is separated from the substrate by a tunnel oxide. A self-aligned word line serves as the control gate, and controls a portion of the channel between the drain and the floating gate. However, the word line has a constant spacing from the channel, the floating gate sidewall, and the floating gate top, as dictated by a uniform layer of silicon oxide film of a thickness of 18 nm. If this thickness is not sufficient to provide adequate breakdown strength between the control gate and the channels, it cannot be thickened without reducing the gate coupling ratio (“GCR”) between the control gate and the floating gate.

### BRIEF SUMMARY OF THE INVENTION

What is desired is a split gate transistor that has reduced sensitivity to punch-through or drain turn-on problems, allows tighter UV V_{T} distribution throughout the memory array, offers significantly lower bit line leakage current and immunity from bit line disturb during Read and Programming, provides a greater gate coupling ratio (allows the use of lower voltage at the X-decoder during erase/programming operation, which in turn permits smaller layout area for the X-decoder) without sacrificing breakdown strength, has reduced tunnel oxide area in the cell (which improves reliability because floating gate length is reduced, viz. is limited only by the lithography), smaller cell size, and larger cell current due to smaller floating gate channel length.

These and other advantages are individually or collectively realized by the various embodiments of the present invention. One embodiment of the present invention is a nonvolatile floating gate memory cell comprising a semiconductor substrate; a first doped region disposed in the semiconductor substrate; a second doped region disposed in the semiconductor substrate and spaced apart from the first doped region, a channel region being defined in the semiconductor substrate between the first and second doped regions; a floating gate disposed over a first part of the channel region and insulated therefrom by a first dielectric, the first dielectric being a tunnel dielectric and the floating gate having a top and a sidewall; and a control gate. The control gate has first and second sections respectively disposed upon the top and the sidewall of the floating gate, the second section of the control gate being insulated from the sidewall of the floating gate by a second dielectric, disposed over a second part of the channel adjacent the first doped region, and insulated from the second part of the channel by the first dielectric and the second dielectric.

Another embodiment of the present invention is a nonvolatile floating gate memory cell comprising a semiconductor substrate; a first doped region disposed in the semiconductor substrate; a second doped region disposed in the semiconductor substrate and spaced apart from the first doped region, a channel region being defined in the semiconductor substrate between the first and second doped regions; a floating gate disposed over a first part of the channel region and insulated therefrom by a tunnel dielectric, the floating gate having a top and first and second sidewalls on opposite sides thereof; and a control gate. The control gate has first, second and third sections respectively disposed upon the top, first sidewall, and the second sidewall of the floating gate, the second section of the control gate being disposed over a second part of the channel adjacent the first doped region, and the third section of the control gate being disposed over a third part of the channel adjacent the second doped region.

Another embodiment of the present invention is a method of forming a nonvolatile floating gate memory cell, comprising defining an active area in a semiconductor substrate; forming a first dielectric over the active area, the first dielectric being a thin dielectric for allowing electron tunneling; forming a strip of floating gate material over the first dielectric, the strip having a top and first and second sidewalls on opposite edges thereof; forming a first spacer upon the first sidewall of the strip; implanting a dopant into the semiconductor substrate aligned at least in part to the first spacer; removing the first spacer; forming a second dielectric over the strip and the substrate; depositing a layer of control gate material over the second dielectric; forming a word line mask over the control gate material; and etching the control gate material layer, the second dielectric layer, and the strip through the word line mask to form a word line in self-alignment with the floating gate material and having a first control gate section along the first sidewall. At least part of the first control gate section and at least part of the floating gate overlay a channel region of the semiconductor substrate.

Another embodiment of the present invention is a method of forming a nonvolatile floating gate memory cell, comprising defining an active area in a semiconductor substrate; forming a first dielectric over the active area, the first dielectric being a thin dielectric for allowing electron tunneling; forming a strip of floating gate material over the first dielectric, the strip having a top and first and second sidewalls on opposite edges thereof; forming a first spacer of a predetermined thickness upon the first sidewall of the strip; implanting a dopant into the semiconductor substrate aligned at least in part to the first spacer; removing the first spacer; forming a second dielectric of a predetermined thickness over the strip and the first dielectric in proximity to the first sidewall; depositing a layer of control gate material of a predetermined thickness over the second dielectric, the thickness of the second dielectric being less than the thickness of the first spacer, and the thickness of the second dielectric together with the thickness of the control gate material being greater than the thickness of the first spacer; forming a word line mask; and etching the control gate material layer, the second dielectric layer, and the strip through the word line mask to form a word line in self-alignment with the floating gate material and insulated from the substrate by the first and second dielectrics, and a floating gate insulated from the substrate by the first dielectric.

Another embodiment of the present invention is a method of forming a nonvolatile floating gate memory cell, comprising forming a first doped region disposed in the semiconductor substrate; forming a second doped region disposed in the semiconductor substrate and spaced apart from the first doped region, a channel region being defined in the semiconductor substrate between the first and second doped regions; forming a floating gate disposed over a first part of the channel region and insulated therefrom by a first dielectric, the first dielectric being a tunnel dielectric and the floating gate having a top and a sidewall; and forming a control gate having first and second sections respectively disposed upon the top and the sidewall of the floating gate, the second section of the control gate being insulated from the sidewall of the floating gate by a second dielectric, disposed over a second part of the channel adjacent the first doped region, and insulated from the second part of the channel by the first dielectric and the second dielectric.

### BRIEF DESCRIPTION OF THE SEVERAL VIEWS OF THE DRAWINGS

FIG. 1 is a graph showing typical prior art relationships of channel length to lithographic resolution.

FIG. 2 is a cross-section view of two symmetrical floating gate memory cells after fabrication of the control gates thereof, in accordance with the present invention.

FIG. 3 is a cross-section view of the memory cells of FIG. 2 in an early stage of fabrication, specifically after patterning of the floating gate etch mask.

FIG. 4 is a cross-section view of the memory cells of FIG. 2 in an early stage of fabrication, specifically after spacer formation and bit-line implant.

FIG. 5 is a cross-section view of the memory cells of FIG. 2 in an early stage of fabrication, specifically after spacer removal and inter-poly dielectric formation.

FIG. 6 is a layout diagram for an array of memory cells like the memory cells of FIG. 2, in an intermediate stage of completion.

FIG. 7 is a cross-section view of two asymmetrical floating gate memory cells after fabrication of the control gates thereof, in accordance with the present invention.

FIG. 8 is a cross-section view of the memory cells of FIG. 7 in an early stage of fabrication, specifically after spacer formation but prior to bit line implant.

FIG. 9 is a layout diagram for an array of memory cells like the memory cells of FIG. 7, in an intermediate stage of completion.

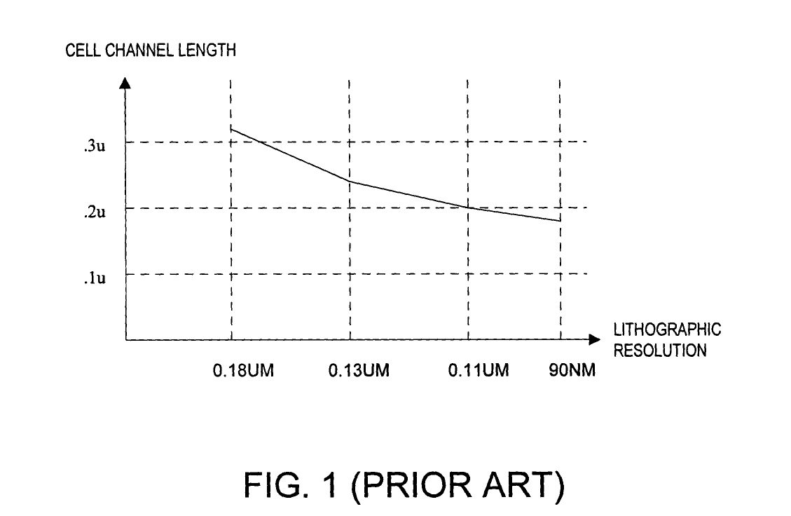

### DETAILED DESCRIPTION OF THE INVENTION, INCLUDING THE BEST MODE

While the structures and fabrication processes described herein are useful in a variety of flash memory cell fabrication technologies, whether or not contactless, the examples described herein are especially favorably applied to a contactless array technology. Contactless array technology generally yields smaller memory cells than other memory array technologies, so that the capability of the method and structure described herein to further reduce the cell size in contactless array technology makes the techniques described herein particularly advantageous for high density flash memory applications. The structures described herein may also be programmed and erased in any suitable way, including CHE programming and channel FN erase as well as other techniques used in conventional floating-gate-based flash memory arrays.

Each of the innovative flash memory cells described herein has a novel split-gate structure in which the channel region underlies a floating gate of minimum lithography dimension, as well as one or more portions of the control gate that extend along one or more sidewalls of the floating gate. The length of the channel underlying the control gate sidewall portions is independent of the thickness of the floating gate sidewall portions and is smaller than and independent of the minimum lithography dimension. Preferably, the control gate is part of a continuous word line extending over a row of many substantially identical memory cells. Due to the ability of the control gate to control the channel directly, punch-through and drain turn-on problems do not arise in the unselected cell on the same bit line as the selected cell, so that the need for a long channel to control these problems is avoided. Indeed, channel length need be no longer that the minimum lithography dimension (the channel portion underlying the floating gate) plus a sufficient additional length to account for the thickness of the inter-poly dielectric on the control gate sidewall or sidewalls, and for sufficient direct control of the channel by the control gate.

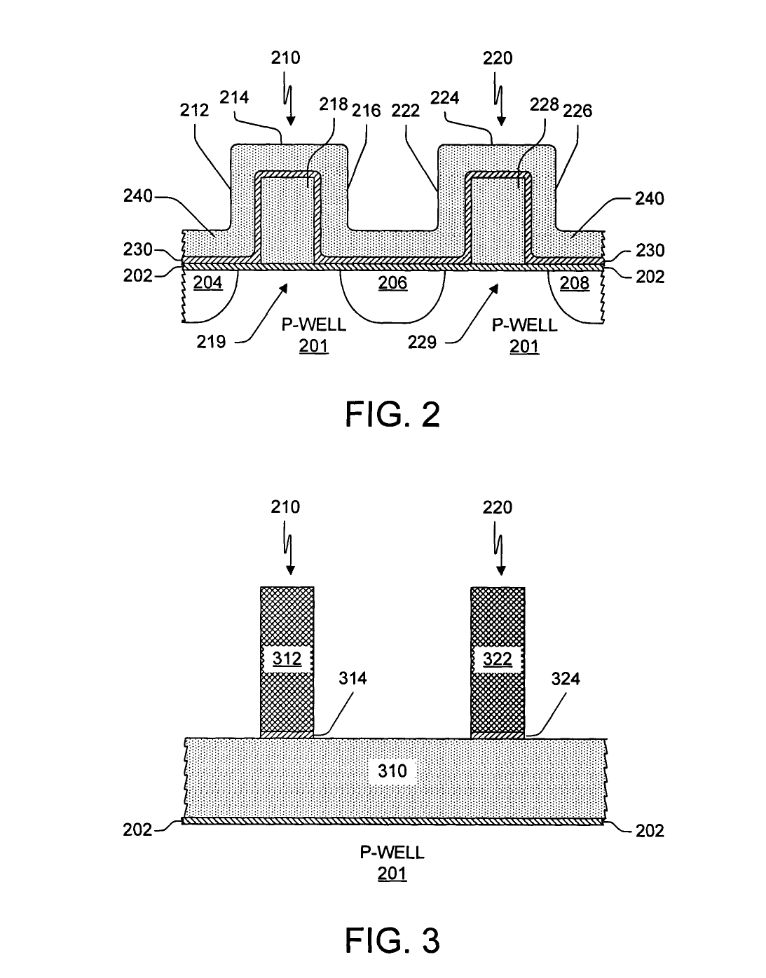

A cross-sectional view of two symmetrical floating gate memory cells 210 and 220 that are adjacent one another along a row is shown in FIG. 2. The memory cells 210 and 220 are shown in an intermediate stage of fabrication, just after a word line poly etch. In the cell 210, two N+ regions 204 and 206 diffused into the p-well 201 serve as source and drain, with a channel region 219 being defined therebetween. A floating gate 218 is positioned over the channel region 219. Advantageously, the dimension of the floating gate 218 may be about as small as the minimum lithographic resolution limit of the process. A word line 240 includes control gate top section 214 and control gate sidewall sections 212 and 216. Control gate sidewall sections 214 and 216 extend downward in proximity to the channel region 219 to exert direct control over current flow in the channel. Illustratively, a tunnel dielectric 202 separates the floating gate 218 from the channel region 219, and an inter-poly dielectric 230 as well as the tunnel dielectric 202 separates the control gate sidewall sections 212 and 216 from the channel region 219. Observe that the channel region 219 underlies the floating gate 218 as well as the control gate sidewall sections 212 and 216, so that current flow in the channel region 219 is controlled by both the floating gate 218 and the word line 240. Observe also that the length of the channel region 219 under the control gate sidewall sections 212 and 216 is not dependent on the thickness of the control gate sidewall sections 212 and 216. It will be appreciated that the length of the channel region 219 under control of the gate sidewall sections 212 and 216 need be only long enough for the control gate sidewall sections 212 and 216 to exert sufficient control over current flow through channel region 219.

Memory cell 220 is similar to cell 210. Specifically, in the cell 220, two N+ regions 206 and 208 diffused into the p-well 201 serve as source and drain, with a channel region 229 being defined therebetween. A floating gate 228 is positioned over the channel region 229. The dimension of the floating gate 228 may be about as small as the minimum lithographic resolution limit of the process. The word line 240 further includes control gate top section 224 and control gate sidewall sections 222 and 226. Control gate sidewall sections 224 and 226 extend downward in proximity to the channel region 229 to exert direct control over current flow in the channel. Illustratively, the tunnel dielectric 202 separates the floating gate 228 from the channel region 229, and the inter-poly dielectric 230 as well as the tunnel dielectric 202 separates the control gate sidewall sections 222 and 226 from the channel region 229. Observe that the channel region 229 underlies the floating gate 228 as well as the control gate sidewall sections 222 and 226, so that current flow in the channel region 229 is controlled by both the floating gate 228 and the word line 240. The length of the channel region 229 under the control gate sidewall sections 222 and 226 need be only long enough for the control gate sidewall sections 222 and 226 to exert sufficient control over current flow through channel region 229.

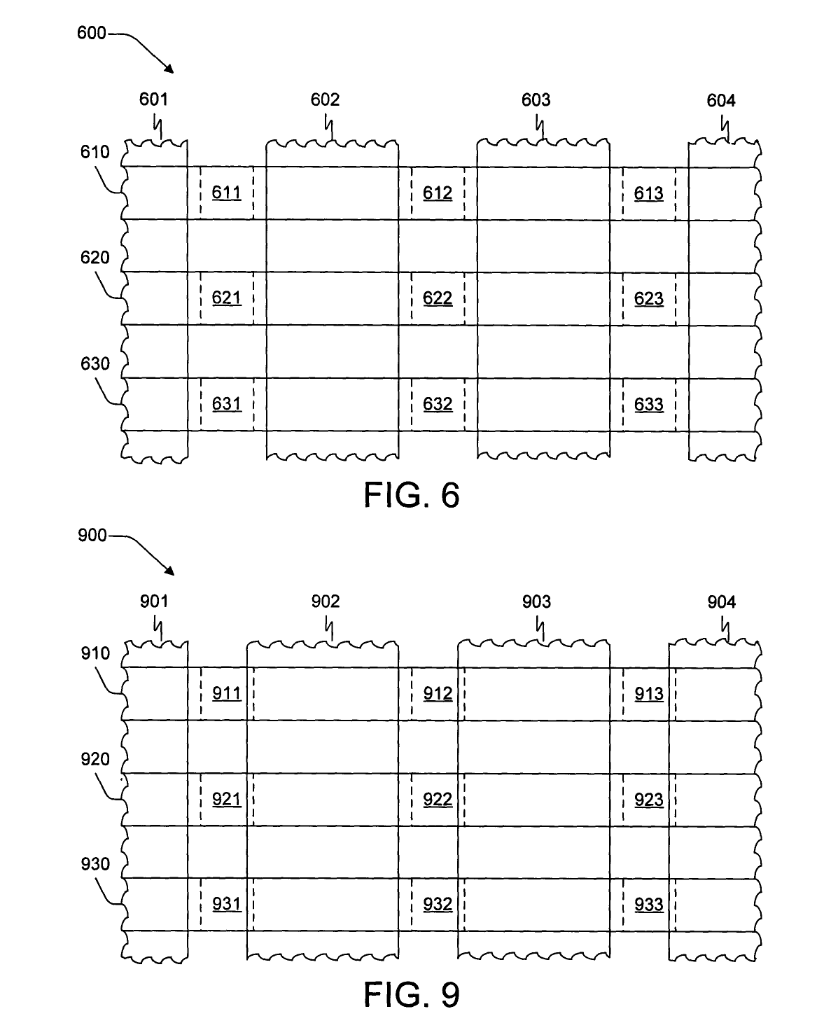

FIG. 6 is a layout diagram showing a layout 600 of memory cells like the memory cells 210 and 220. Minimum lithographic dimension floating gates 611, 612 and 613, 621, 622 and 623, and 631, 632 and 633 are laid out in a regular array. They are spaced apart from one another in the direction of diffusion bit lines 601, 602, 603 and 604 by the minimum lithographic dimension. In the direction of word lines 610, 620 and 630, their minimum spacing is determined by the minimum requirement of the control gate channel length and the minimum requirement of the diffusion bit line width (which in turn is determined at least in part by the resistance requirement of the diffusion bit line). Floating gates 611, 612 and 613 are parts of memory cells controlled by the word line 610. Similarly, floating gates 621, 622 and 623 are parts of memory cells controlled by the word line 620, and floating gates 631, 632 and 633 are parts of memory cells controlled by the word line 630. The diffusion bit lines 601, 602, 603 and 604 form the sources and drains of the various memory cells in the layout 600.

The degree of coupling between the control gate and the floating gate and the degree of control of the channel by the control gate are matters of design when guided by the following criteria. The degree of coupling between the control gate and the floating gate is dependent on the size of the floating gate, the amount of the floating gate capacitively coupled to the control gate, and the type and thickness of the intervening dielectric. The degree of control of the channel by the control gate is dependent on the amount that the control gate overlaps the channel and the thickness of the tunnel dielectric.

The following are illustrative dimensions for the device shown in FIG. 2 when placed in the layout 600 shown in FIG. 6, it being understood that the dimensions are by way of example only, and that other dimensions that achieve a suitable degree of coupling between the control gate and the floating gate and a suitable degree of control of the channel by the control gate are suitable as well. In 0.131 μm process technology, for example, the width and height of the floating gate are 130 nm and 200 nm respectively, the thickness of the inter-poly oxide is 30 nm (for an electrical equivalent of about 20 nm to 25 nm), the thickness of the tunnel oxide 202 is 10 nm, and the control gate direct overlap over the channel region is 40 nm.

An illustrative method of fabricating the cells of FIG. 2 is described with reference to the illustrative process sequence of FIGS. 3, 4 and 5. The method places the cells into a contact-less array with buried drain/source lines to achieve very compact cell size. Furthermore, the two diffusion N+ regions preferably are self-aligned to the floating-gate, thus further minimizing the cell size. It will be appreciated that all materials, dimensions, doping concentrations, doses, energy levels, temperatures, drive-in times, ambient conditions, and all other values for the parameters of the process sequence are described as examples, and that different values may well be selected as a matter of design choice by one of ordinary skill in the art, or otherwise selected to achieve desired characteristics. It will also be appreciated that some additional process operations may be performed to create transistors and other devices peripheral to the memory array, to form contacts and metal lines, and to protect and pacify the integrated circuit. As these operations are not specific to the fabrication of the virtual ground memory cell and as suitable operations are in any event well known in the art, they are not further described herein.

FIG. 3 is a cross-section view of the memory cells 210 and 220 in an early stage of fabrication, specifically after patterning of a gate oxide etch mask to define gates such as 611, 612, 613, 621, 622, 623, 631, 632 and 633 in the intermediate-stage layout diagram of FIG. 6. The process begins with any suitable conventional front-end process. In an illustrative fabrication process, for example, the starting material is ap-type silicon substrate. On the p-type substrate material, a pad oxide layer and silicon nitride layer are deposited and patterned in a manner well known in the art. The field areas are exposed by plasma etching in a manner well known in the art, and shallow trench isolation (“STI”) is formed between the active area in a manner well known in the art. Isolation wells (n-well and p-well) are formed in the active areas in a manner well known in the art. Next and with reference to the p-well 201 in the silicon substrate, a tunnel oxide 202 is formed on the substrate, including the p-well 201, in any manner desired, suitable techniques for forming tunnel oxide being well known in the art in a manner well known in the art. The silicon dioxide “tunnel oxide” layer 202 may be grown, for example, by dry oxidation at atmospheric pressure and relatively low temperature, dry oxidation with HCl, oxidation at reduced total pressures, oxidation at reduced partial pressures of O₂, use of composite oxide films such as oxynitrides, and so forth. Illustratively, the tunnel oxide 202 is about 90 Å to about 100 Å thick.

Following formation of the tunnel oxide layer 202, a polysilicon layer 310 is deposited to an illustrative thickness of 2000Å, although the thickness may be less or greater depending on the degree of coupling desired between the control gate and the floating gate. The polysilicon layer 310 may be formed by any method desired, suitable techniques for forming polysilicon being well known in the art and including depositing polysilicon by, for example, chemical vapor deposition (“CVD”). Preferably the polysilicon layer 310 is lightly phosphorus doped to establish a resistivity of about 4000 to 6000 ohms per square.

Next, an anti-reflecting coat (“ARC”) is formed over the polysilicon layer 310. The ARC material is desirable when forming minimum lithographic dimension structures with photoresist, since it improves the quality of the exposure. Different materials may be used depending on whether any etching of the tunnel oxide over the channel to be controlled by the control gate is desired. Where etching of this area of the tunnel oxide is not desired, the ARC material preferably is an organic material that etches differently than tunnel oxide. Otherwise, a layer of material such as oxynitride (silicon nitride upon thermal oxide) may be used. Such materials and their etching characteristics are well known in the art.

Next, any suitable photoresist layer is deposited, developed and etched to form a floating gate mask having masking features 312 and 322 in the nature of elongated strips (extending perpendicular to the drawing sheet). It will be appreciated that the masking features 312 and 322 may be as narrow as the lithographic resolution limit of the equipment permits. The ARC layer is etch through the floating gate mask by a plasma etch in a manner well known in the art to form ARC strips 314 and 324 respectively underlying the masking features 312 and 322.

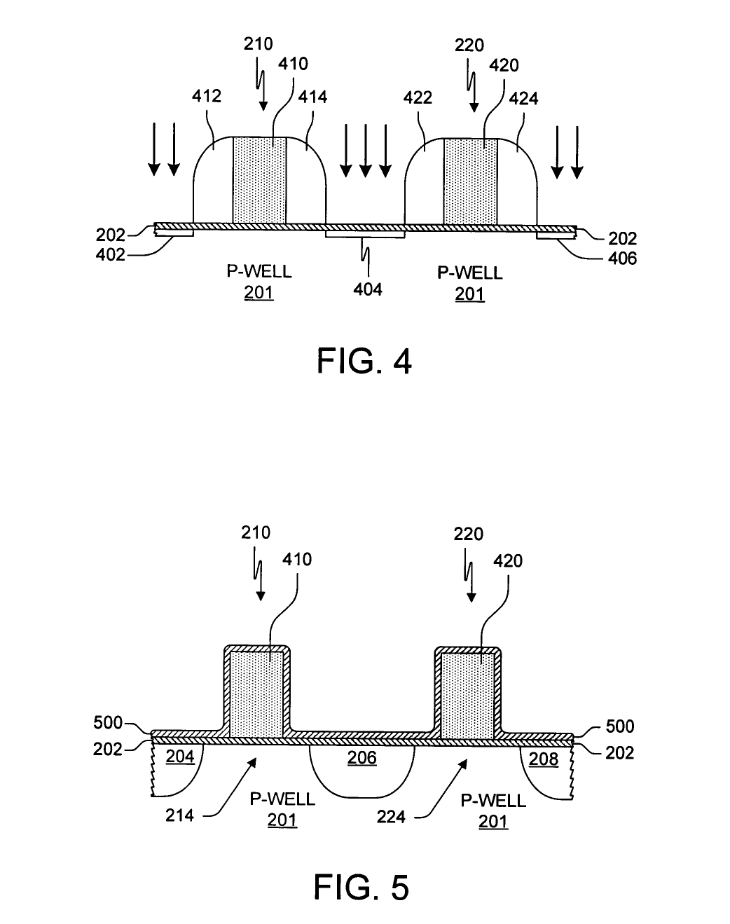

FIG. 4 is a cross-section view of the memory cells 210 and 220 in an early stage of fabrication, specifically after spacer formation and bit-line implant. Resuming from the structure of FIG. 3, the process proceeds with etching of the polysilicon layer 310 by plasma etching in a manner well known in the art to form polysilicon strips 410 and 420. Floating gates such as 611, 612, 613, 621, 622, 623, 631, 632 and 633 are later formed from such polysilicon strips. The resist strips 312 and 322 are removed, preferably using an etching process that does not etch the tunnel oxide layer 202. Next, sacrificial spacers are formed on the sidewalls of the polysilicon strips 410 and 420 by depositing a material such as silicon nitride that can be etched with a chemistry that does not etch the tunnel oxide 202. One technique for forming spacers involves depositing a layer of silicon nitride to an illustrative thickness of 50 nm, followed by an anisotrophic plasma etch for a sufficient duration to remove completely the silicon nitride from the top of the polysilicon strips 410 and 420, as well as from an elongated strip-like section of the surface of the tunnel oxide 202 between the polysilicon strips 410 and 420. As a result, spacers 412 and 414 are formed along the sidewalls of the polysilicon strip 410, and spacers 422 and 424 are formed along the sidewalls of the polysilicon strip 420. The width of the spacers 412, 414 and 422 and 424 establishes the location of the source and drain regions, which in turn define the channel length.

Next, an implant is performed to form the drain/source lines. Where the dopant is an n-type impurity, a suitable implant is phosphorous at a dose of about 3×10¹⁴cm⁻² and an energy of about 30 KeV. The implants 402, 404 and 406 are driven in and activated under suitable conditions as is well known in the art to form the source/drain lines of which the n-type regions such as 204, 206 and 208 (FIG. 5) are part, thereby establishing the length of the channel regions such as 214 and 224. If the source/drain lines are to serve as buried bit lines, their resistance may be reduced by performing an additional implant of a suitable dopant such as arsenic or additional phosphorous, one such technique being described in U.S. patent application Ser. No. 10/358,645, filed Feb. 4, 2003 and entitled “Virtual ground single transistor memory cell, memory array incorporating same, and method of operation thereof,” which hereby is incorporated herein by reference thereto in its entirety, and other suitable techniques being well known in the art.

FIG. 5 is a cross-section view of the memory cells of FIG. 2 in an early stage of fabrication, specifically after spacer removal and gate oxide formation. Resuming from the structure of FIG. 4, the process proceeds with removal of the nitride spacers 412, 414 and 422 and 424 and the ARC strips 314 and 324. This may be done in a variety of different ways. Where the ARC strips 314 and 324 are of an organic material, the nitride spacers 412, 414 and 422 and 424 may be etched in any suitable isotropic etching process that does not etch oxide, followed by removal of the ARC strips 314 and 324 using an organic material etching process that also does not etch the tunnel oxide layer 202. This is the embodiment shown in FIG. 5. Where the ARC strips 314 and 324 are or contain an oxide layer, they may be removed prior to removal of the nitride spacers 412, 414 and 422 and 424 using any desired etching process, including one that etches tunnel oxide, since the tunnel oxide under the nitride spacers 412, 414 and 422 and 424 is protected, followed by removal of the nitride spacers 412, 414 and 422 and 424 by an isotropic etch that does not attack oxide. Alternatively, the nitride spacers 412, 414 and 422 and 424 may be etched in an isotropic etching process, followed by removal of the ARC strips 314 and 324 using any suitable etching process, including processes that etch oxide. This alternative may result in removal of the tunnel oxide 202 except where it is protected by the floating gates 410 and 420.

Next, a suitable inter-poly dielectric layer 500 is formed. The layer 500 serves both as the dielectric between the control gates and floating gates, as well as part of the dielectric between the control gate and the substrate (the other part being portions of the tunnel oxide layer 202). A variety of materials may be used for the inter-poly dielectric 500, including oxide-nitride-oxide (“ONO”). The thickness of the inter-poly dielectric 500 is based on the need to provide adequate breakdown strength between the control gate 230 and the channels 214 and 224 when combined with the tunnel oxide 202 (FIG. 2), while maintaining a sufficient gate coupling ratio (“GCR”) between the control gate 230 and the floating gates 212 and 222. Where the inter-poly dielectric is ONO, suitable thicknesses of the oxide, nitride and oxide constituting layers are 8 nm, 15 nm and 7 nm respectively. If further improvement in the dielectric breakdown strength is required, the middle silicon nitride layer may be thickened. The CGR is also influenced by the thickness of the floating gate, with a higher GCR being achieved by increasing the thickness of the floating gates 212 and 222. Here, polysilicon preferably is deposited to an illustrative thickness of about 2000 Å relative to the typically floating gate thickness of 1500 Å, to achieve a suitable GCR. The GCR decreases as the width of the floating gate decreases and increases as the thickness of the floating gate increases, so that increasing the thickness of the floating gate can compensate for loss in the GCR that would otherwise result by the floating gate being the size of the minimum lithographic dimension.

To achieve the structure of FIG. 2, the process resumes from the structure of FIG. 5 by depositing a suitable layer (not shown) of word line material such as polysilicon or a polycide (tungsten or cobalt silicide), which along with the inter-poly dielectric layer 500 is then defined using a suitable mask and plasma etching in a manner well known in the art to form word lines such as 240 that include control gate sections such 212, 214 and 216 for the transistor 210, and control gate sections such 222, 224 and 226 for the transistor 220. Etching is continued through the inter-poly dielectric and the polysilicon layer to complete definition of the floating gates 218 and 228. The resulting floating gates 218 and 228 thereby have two opposite edges that are self-aligned with the word line 240 (FIG. 2) and spaced away from the edges of neighboring floating gates preferably by the minimum lithographic dimension. This later condition is shown in FIG. 6, wherein floating gate 621 is spaced from floating gate 611 and floating gate 631 by about the minimum lithographic dimension, floating gate 622 is spaced from floating gate 612 and floating gate 632 by about the minimum lithographic dimension, and floating gate 623 is spaced from floating gate 613 and floating gate 633 by about the minimum lithographic dimension.

The integrated circuit is completed with subsequent process operations to form various additional layers of insulation, contacts, word line strapping, metal lines, and protective overcoats, in a manner well known in the art. Steps to complete peripheral circuits may be performed, followed by the back-end processing, suitable process steps being well known in the art. Other process operations may be added to improve various aspects of the integrated circuit. As these operations are not specific to the fabrication of the novel split-gate cell and are in any event well known in the art, they are not further described herein.

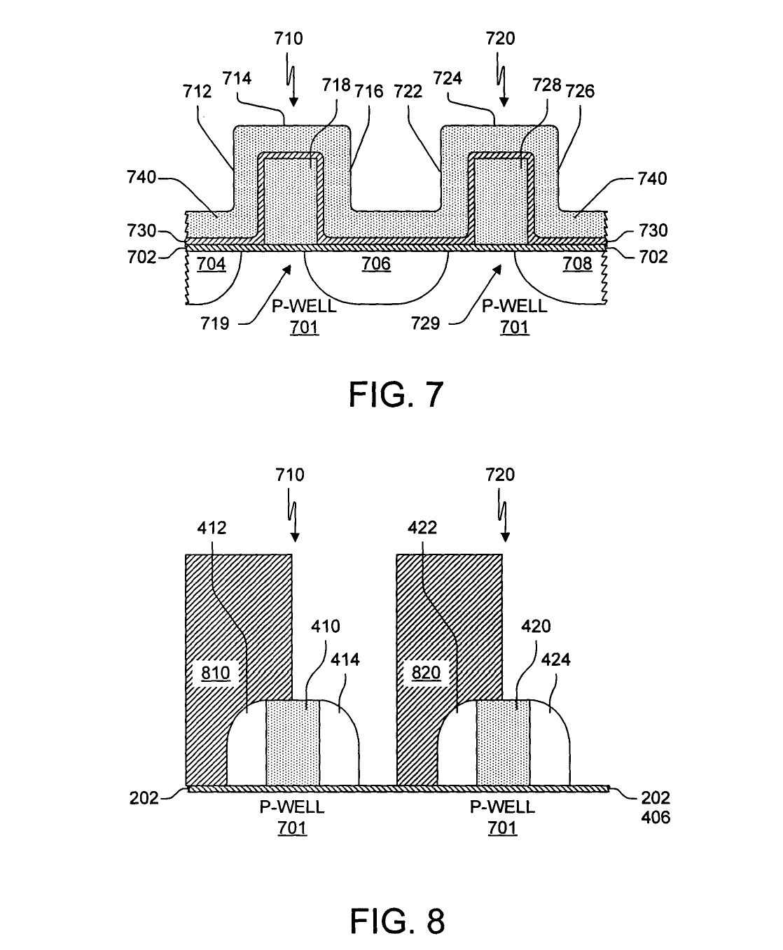

A cross-sectional view of two asymmetrical floating gate memory cells 710 and 720 that are adjacent one another along a row is shown in FIG. 7. Cells 710 and 720 are similar to the cells 210 and 220 shown in FIG. 2 except that they are asymmetrical and have a shorter channel length not too much longer than the minimum lithographic resolution. FIG. 7 shows the cells 710 and 720 in an intermediate stage of fabrication, just after a word line poly etch.

In the cell 710, two N+ regions 704 and 706 diffused into the p-well 701 serve as source and drain, with a channel region 719 being defined therebetween. A floating gate 718 is positioned over the channel region 719. Advantageously, the dimension of the floating gate 718 may be about as small as the minimum lithographic resolution limit of the process. A word line 740 includes control gate top section 714 and control gate sidewall sections 712 and 716. Control gate sidewall section 714 extends downward in proximity to the channel region 719 to exert direct control over current flow in the channel. Illustratively, a tunnel dielectric 702 separates the floating gate 718 from the channel region 719, and an inter-poly dielectric 730 as well as the tunnel dielectric 702 separates the control gate sidewall section 712 from the channel region 719. Observe that the channel region 719 underlies the floating gate 718 as well as the control gate sidewall section 712, so that current flow in the channel region 719 is controlled by both the floating gate 718 and the word line 740. Observe also that the length of the channel region 719 under the control gate sidewall section 712 is not dependent on the thickness of the control gate sidewall section 712. It will be appreciated that the length of the channel region 719 under control of the gate sidewall section 712 need be only long enough for the control gate sidewall section 712 to exert sufficient control over current flow through channel region 719.

Memory cell 720 is similar to cell 710. Specifically, in the cell 720, two N+ regions 706 and 708 diffused into the p-well 701 serve as source and drain, with a channel region 729 being defined therebetween. A floating gate 728 is positioned over the channel region 729. The dimension of the floating gate 728 may be about as small as the minimum lithographic resolution limit of the process. The word line 740 further includes control gate top section 724 and control gate sidewall sections 722 and 726. Control gate sidewall section 724 extends downward in proximity to the channel region 729 to exert direct control over current flow in the channel. Illustratively, the tunnel dielectric 702 separates the floating gate 728 from the channel region 729, and the inter-poly dielectric 730 as well as the tunnel dielectric 702 separates the control gate sidewall section 722 from the channel region 729. Observe that the channel region 729 underlies the floating gate 728 as well as the control gate sidewall section 722, so that current flow in the channel region 729 is controlled by both the floating gate 728 and the word line 740. The length of the channel region 729 under the control gate sidewall section 722 need be only long enough for the control gate sidewall section 722 to exert sufficient control over current flow through channel region 729.

FIG. 9 is a layout diagram showing a layout 900 of memory cells like the memory cells 710 and 720. Minimum lithographic dimension floating gates 911, 912 and 913, 921, 922 and 923, and 931, 932 and 933 are laid out in a regular array. They are spaced apart from one another in the direction of diffusion bit lines 901, 902, 903 and 904 by the minimum lithographic dimension. In the direction of word lines 910, 920 and 930, their minimum spacing is determined by the minimum requirement of the control gate channel length and the minimum requirement of the diffusion bit line width (which in turn is determined at least in part by the resistance requirement of the diffusion bit line). Floating gates 911, 912 and 913 are parts of memory cells controlled by the word line 910. Similarly, floating gates 921, 922 and 923 are parts of memory cells controlled by the word line 920, and floating gates 931, 932 and 933 are parts of memory cells controlled by the word line 930. The diffusion bit lines 901, 902, 903 and 904 form the sources and drains of the various memory cells in the layout 900.

The memory cells of FIG. 7 illustratively may be formed with a process that is similar to the process for forming the memory cells of FIG. 2, except that one of the spacers is removed from each of the floating gates during fabrication. FIG. 8 shows the memory cells 710 and 720 in the same stage of fabrication shown in FIG. 4, but prior to the implant step. Spacers are formed on the sidewalls of the polysilicon strips 410 and 420 as in the process for forming the FIG. 2 memory cell, thereby leaving spacers 412 and 414 and ARC strip 812 on the polysilicon strip 410, and spacers 422 and 424 and ARC strip 822 on the polysilicon strip 420. However, prior to implant, a layer of photoresist is deposited and patterned to form protective features 810 and 820 over the spacers 412 and 422. The exposed spacers 414 and 424 are removed by an isotropic nitride etch, the protected spacers 412 and 422 being left intact. The resist features 810 and 820 are removed by a suitable etch, and implant proceeds as in the process for the memory cell of FIG. 2.

The description of the invention and its applications as set forth herein is illustrative and is not intended to limit the scope of the invention. Variations and modifications of the embodiments disclosed herein are possible, and practical alternatives to and equivalents of the various elements of the embodiments are known to those of ordinary skill in the art. These and other variations and modifications of the embodiments disclosed herein may be made without departing from the scope and spirit of the invention.

1. A nonvolatile floating gate memory cell comprising:
a semiconductor substrate;
a first doped region disposed in the semiconductor substrate;
a second doped region disposed in the semiconductor substrate and spaced apart from the first doped region, a channel region being defined in the semiconductor substrate between the first and second doped regions;
a floating gate disposed over a first part of the channel region and insulated therefrom by a first dielectric, the first dielectric being a tunnel dielectric and the floating gate having a top and a sidewall; and
a control gate having first and second sections respectively disposed upon the top and the sidewall of the floating gate, the second section of the control gate being insulated from the sidewall of the floating gate by a second dielectric, disposed over a second part of the channel adjacent the first doped region, and insulated from the second part of the channel by the first dielectric and the second dielectric.

2. The memory cell of claim 1 wherein the second section of the control gate is further disposed over at least part of the first doped region and is insulated therefrom by the first dielectric and the second dielectric.

3. The memory cell of claim 2 wherein the first section of the control gate is insulated from the top of the floating gate by the second dielectric.

4. The memory cell of claim 1 wherein:
the floating gate has an additional sidewall; and
the control gate further has a third section disposed upon the additional sidewall of the floating gate, and insulated therefrom by the second dielectric.

5. The memory cell of claim 4 wherein the floating gate is further disposed over at least part of the second doped region and insulated therefrom by the first dielectric.

6. The memory cell of claim 5 wherein:
the second section of the control gate is further disposed over at least part of the first doped region and is insulated therefrom by the first dielectric and the second dielectric; and
the third section of the control gate is further disposed over at least part of the second doped region and is insulated therefrom by the first dielectric and the second dielectric.

7. The memory cell of claim 6 wherein the first section of the control gate is insulated from the top of the floating gate by the second dielectric.

8. The memory cell of claim 4 wherein the third section of the control gate is disposed over a third part of the channel adjacent the second doped region and insulated from the third part of the channel by the first dielectric and the second dielectric.

9. The memory cell of claim 8 wherein:
the second section of the control gate is further disposed over at least part of the first doped region and is insulated therefrom by the first dielectric and the second dielectric; and
the third section of the control gate is further disposed over at least part of the second doped region and is insulated therefrom by the first dielectric and the second dielectric.

10. The memory cell of claim 9 wherein the first section of the control gate is insulated from the top of the floating gate by the second dielectric.

11. A nonvolatile floating gate memory cell comprising:
a semiconductor substrate;
a first doped region disposed in the semiconductor substrate;
a second doped region disposed in the semiconductor substrate and spaced apart from the first doped region, a channel region being defined in the semiconductor substrate between the first and second doped regions;
a floating gate disposed over a first part of the channel region and insulated therefrom by a tunnel dielectric, the floating gate having a top and first and second sidewalls on opposite sides thereof; and
a control gate having first, second and third sections respectively disposed upon the top, first sidewall, and the second sidewall of the floating gate, the second section of the control gate being disposed over a second part of the channel adjacent the first doped region, and the third section of the control gate being disposed over a third part of the channel adjacent the second doped region.

12. The memory cell of claim 11 wherein:
the control gate and the floating gate comprise polysilicon;
the first section of the control gate is separated from the top of the floating gate by an inter-poly dielectric;
the second section of the floating gate is separated from the first sidewall of the floating gate by the inter-poly dielectric, and is separated from the second part of the channel by the tunnel oxide and the inter-poly dielectric; and
the third section of the floating gate is separated from the second sidewall of the floating gate by the inter-poly dielectric, and is separated from the third part of the channel by the tunnel oxide and the inter-poly dielectric.

13. The memory cell of claim 11 wherein:
the control gate and the floating gate comprise polysilicon;
the first section of the control gate is separated from the top of the floating gate by an inter-poly dielectric;
the second section of the floating gate is separated from the first sidewall of the floating gate by the inter-poly dielectric, and is separated from the second part of the channel by the inter-poly dielectric; and
the third section of the floating gate is separated from the second sidewall of the floating gate by the inter-poly dielectric, and is separated from the third part of the channel by the inter-poly dielectric.

14. A method of forming a nonvolatile floating gate memory cell, comprising:
defining an active area in a semiconductor substrate;
forming a first dielectric over the active area, the first dielectric being a thin dielectric for allowing electron tunneling;
forming a strip of floating gate material over the first dielectric, the strip having a top and first and second sidewalls on opposite edges thereof;
forming a first spacer upon the first sidewall of the strip;
implanting a dopant into the semiconductor substrate aligned at least in part to the first spacer;
removing the first spacer;
forming a second dielectric over the strip and the substrate;
depositing a layer of control gate material over the second dielectric; forming a word line mask over the control gate material; and
etching the control gate material layer, the second dielectric layer, and the strip through the word line mask to form a word line in self-alignment with the floating gate material and having a first control gate section along the first sidewall;
wherein at least part of the first control gate section and at least part of the floating gate overlay a channel region of the semiconductor substrate.

15. The method of claim 14 further comprising:
forming a second spacer upon the second sidewall of the strip;
implanting the dopant into the semiconductor substrate aligned at least in part to the second spacer; and
removing the second spacer prior to the second dielectric forming step;
wherein the word line of the etching step further has a second control gate section along the second sidewall; and
wherein at least part of the second control gate section overlays the channel region.

16. The method of claim 14 wherein the second dielectric forming step comprises depositing the second dielectric directly upon the first dielectric in proximity to the first sidewall.

17. A method of forming a nonvolatile floating gate memory cell, comprising:
defining an active area in a semiconductor substrate;
forming a first dielectric over the active area, the first dielectric being a thin dielectric for allowing electron tunneling;
forming a strip of floating gate material over the first dielectric, the strip having a top and first and second sidewalls on opposite edges thereof;
forming a first spacer of a predetermined thickness upon the first sidewall of the strip;
implanting a dopant into the semiconductor substrate aligned at least in part to the first spacer;
removing the first spacer;
forming a second dielectric of a predetermined thickness over the strip and the first dielectric in proximity to the first sidewall;
depositing a layer of control gate material of a predetermined thickness over the second dielectric, the thickness of the second dielectric being less than the thickness of the first spacer, and the thickness of the second dielectric together with the thickness of the control gate material being greater than the thickness of the first spacer;
forming a word line mask; and
etching the control gate material layer, the second dielectric layer, and the strip through the word line mask to form a word line in self-alignment with the floating gate material and insulated from the substrate by the first and second dielectrics, and a floating gate insulated from the substrate by the first dielectric.

18. The method of claim 17 further comprising:
forming a second spacer having a thickness equal to the thickness of the first spacer on the second sidewall of the strip;
implanting the dopant into the semiconductor substrate aligned at least in part to the second spacer; and
removing the second spacer prior to the second dielectric forming step.

19. A method of forming a nonvolatile floating gate memory cell, comprising:
forming a first doped region disposed in the semiconductor substrate;
forming a second doped region disposed in the semiconductor substrate and spaced apart from the first doped region, a channel region being defined in the semiconductor substrate between the first and second doped regions;
forming a floating gate disposed over a first part of the channel region and insulated therefrom by a first dielectric, the first dielectric being a tunnel dielectric and the floating gate having a top and a sidewall; and
forming a control gate having first and second sections respectively disposed upon the top and the sidewall of the floating gate, the second section of the control gate being insulated from the sidewall of the floating gate by a second dielectric, disposed over a second part of the channel adjacent the first doped region, and insulated from the second part of the channel by the first dielectric and the second dielectric.

20. The method of claim 19 wherein the control gate forming step further comprises forming the second section of the control gate over at least part of the first doped region and insulated therefrom by the first dielectric and the second dielectric.
